(19) United States
(12) Patent Application Publication
(10) Pub. No.: US 2007/0170945 A1
(43) Pub. Date: Jul. 26, 2007

(54) Printed circuit board and method of use thereof

(76) Inventors: Paul Skow, Bramley (GB); James William Belford, Guiseley (GB); Colin McGonigal, Saltaire (GB)

Correspondence Address: HEAD, JOHNSON & KACHIGIAN, 228 W 17TH PLACE, TULSA, OK, 74119, US

(21) Appl. No.: 11/698,494

(22) Filed: Jan. 26, 2007

(30) Foreign Application Priority Data
Jan. 26, 2006 (GB) 0601543.2

(51) Int. Cl. G01R 31/26

(52) U.S. Cl. 324/765

(57) ABSTRACT

A printed circuit board (PCB) is provided. The PCB has at least a first surface and a second surface. One or more pre-defined areas defined on the first surface have connection to or comprise a PCB plane for the location of one or more electrical components thereon in use. One or more test pads provided on the second surface allow electrical testing of said PCB and/or one or more electrical components located thereon. Two or more connectivity points are provided on the first surface in each of said pre-defined areas. The connectivity points are a spaced distance apart and are substantially electrically isolated from each other in a first condition. The connectivity points are capable of electrical connection in a second condition.

### CROSS-REFERENCES TO RELATED APPLICATION

This United States Application claims priority to British Patent Application No. 0601543.2 filed Jan. 26, 2006.

### STATEMENT REGARDING FEDERALLY SPONSORED RESEARCH OR DEVELOPMENT

Not Applicable

### THE NAMES OF THE PARTIES TO A JOINT RESEARCH AGREEMENT

Not Applicable

### INCORPORATION-BY-REFERENCE OF MATERIAL SUBMITTED ON A COMPACT DISC

Not Applicable

### BACKGROUND OF THE INVENTION

This invention relates to a printed circuit board (PCB) and, particularly but not necessarily exclusively, to a PCB which allows the coverage of solder of an electronic component to the printed circuit board (PCB) to be measured and also to a method of use thereof.

Conventional PCBs typically have an upper surface and a lower surface, and one or more electrical components are located with the upper and/or lower surface in use. One or more PCB planes are defined on the surfaces of the board provided and typically provide areas of lower impedance between power and ground and to allow one or more electrical components to be connected to the same. For example, if an electrical component is likely to generate a large amount of heat during use and requires a connection to a PCB circuit (typically ground) to rapidly dissipate this heat, the electrical component is connected to a PCB plane on the board. It is important that adequate solder is provided between the PCB plane and an electrical component being connected thereto to ensure adequate heat dissipation from the component through the PCB in use. This heat dissipation is typically essential for the electrical component to function correctly in use.

One or more test pads are provided on PCBs, typically on a surface opposite to the surface on which the electrical components are attached, to allow electrical tests to be carried out on the PCB and/or electrical components. The test pads typically include an electrical test connection point in communication with a via which passes through the board to the opposite surface. Function tests are typically undertaken in respect of assembled PCBs using these test pads prior to shipping to ensure all components on the board are fully operational. Failure of one or more of the function tests can be as a result of inadequate levels of solder being provided between the PCB plane and an electrical component, thus causing overheating of the electrical component. However, conventionally, in order to test whether failure of the board is due to insufficient solder between the component and the PCB plane, an X-Ray typically has to be taken of the PCB. This is a time consuming and expensive method.

### BRIEF SUMMARY OF THE INVENTION

it is an aim of the present invention to provide a PCB which allows the level or degree of solder contact between an electrical component and a surface or pre-defined area of the PCB to be determined.

It is a further aim of the present invention to provide a method which tests whether sufficient solder has been used between an electrical component and a pre-defined area of the PCB.

It is a yet further aim of the present invention to provide apparatus to allow the level or degree of solder contact between an electrical component and a surface or pre-defined area of the PCB to be determined.

According to a first aspect of the present invention there is provided a printed circuit board (PCB), the PCB having at least a first surface and a second surface, one or more pre-defined areas defined on the first surface having connection to or comprising a PCB plane for the location of one or more electrical components thereon in use, and one or more test pads provided on the second surface to allow electrical testing of the PCB and/or one or more electrical components located thereon, and wherein two or more connectivity points are provided on the first surface in each of the pre-defined areas, the connectivity points being a spaced distance apart and being substantially electrically isolated from each other in a first condition, the connectivity points capable of electrical connection in a second condition.

Thus, by providing a plurality of connectivity points or test points on a planed area of the PCB, such as a ground plane or ground slug, the level of solder used on the PCB area to allow attachment of an electrical component therewith can be determined by measuring the electrical connectivity between the connectivity points using the test pads on the opposite surface of the PCB. The introduction of the connectivity points on the board is a simple process and removes the requirement for the PCB to be x-rayed in order to determine whether adequate solder levels have been used between the electrical component and the PCB plane.

Preferably, electrical conducting means are located between the two or more connectivity points to provide the second condition. The electrical conducting means is typically a sufficient amount or coverage of solder to form electrical connection between the spaced apart connectivity points. Thus, application of sufficient solder between the electrical component and the PCB plane provides the second condition wherein the connectivity points are no longer electrically isolated.

Preferably, the number of connectivity points provided on the pre-defined area is sufficient to allow the level of solder connectivity to be determined between the area and the electrical component attached thereto in use. For example, five or more connectivity points are typically required on the pre-defined area in one embodiment.

Typically, approximately 50% solder coverage is required between the electrical component and/or the two or more connectivity points and the pre-defined area to provide the second condition.

Preferably, the electrical component is an integrated circuit (IC) in one example. The IC generates a large amount of heat in use which needs to be dissipated rapidly through the PCB to ensure adequate functioning of the IC.

Preferably, each connectivity point provided on the pre-defined area includes an inner portion and an outer portion. The inner and outer portions of each connectivity point are preferably substantially electrically isolated in the first condition. A small gap or space is provided between the inner and outer portions and the gap provides the electrical isolation in the first condition. The gap is bridged by the electrical conducting means or solder when adequate solder is used between the component and the pre-defined area in use, thereby allowing electrical connection between the inner and outer portions of the connectivity points. Thus, substantially no solder resist is located in the gap between the inner and outer portions on the PCB plane of the PCB.

Preferably, an inner portion of each connectivity point on the first surface communicates with a test pad on the opposite or second surface via at least one via. Thus, each inner portion of each connectivity point communicates with a separate test pad.

Preferably, the outer portion of each connectivity point is typically electrically connected or connectable to at least one other connectivity point in the pre-defined area, and further preferably to all of the other connectivity points in the area in the first and/or second condition. This allows the electrical conductivity of any connectivity point on the PCB to be tested relative to any other connectivity point in the pre-defined area.

Thus, in the first condition, the inner portion of each point communicates with a test pad and the outer portion of each point communicates with at least one other outer portion in the pre-defined area. Electrical connectivity of the outer portions cannot be measured since the inner and outer portion within each connectivity point are electrically isolated in the first condition and thus the outer portion is not in communication with a test pad. However, in the second condition, solder bridges the gap between the outer and inner portions of a connectivity point, thereby allowing electrical conduction between the inner and outer portions and thus electrical conductivity to be measured between the outer portion and the test pad associated with the inner portion.

The connectivity points can be any suitable shape, such as circular, square and/or the like.

Preferably, the inner and/or outer portions are substantially continuous in form.

Further, preferably, the inner and/or outer portions have a space located therein/therebetween. For example, both the inner and outer portions can be substantially annular in form.

Test pads are conventionally provided on PCBs and are normally geographically distributed evenly across the board to allow electrical testing of components provided on the board to be undertaken. A via typically connects each test pad to a connectivity point and the test pad and the connectivity point are preferably located in substantial vertical alignment on the opposing surfaces of the PCB (i.e. each via is arranged substantially perpendicularly to the first and second surfaces of the board). In one embodiment, the electrical testing undertaken using the test pads to determine the conductivity between the connectivity points on the opposite surface is typically a “bed of nails” in-circuit test (ICT).

According to a second aspect of the present invention, there is provided a method for determining the amount of solder provided between two connectivity points in a pre-defined area of a PCB. The PCB has at least a first surface and a second surface, the pre-defined area defined on the first surface and having connection to or comprising a PCB plane for the location of one or more electrical components thereon in use, and one or more test pads provided on the second surface to allow electrical testing of the PCB and/or one or more electrical components located thereon, and wherein the two or more connectivity points are provided on the first surface in each of the pre-defined areas, the connectivity points being a spaced distance apart and substantially electrically isolated from each other in a first condition, the connectivity points capable of electrical connection in a second condition upon application of sufficient solder and the method including the step of testing the electrical connectivity between the connectivity points using the test pads.

According to a further aspect of the present invention there is provided solder test apparatus, the apparatus including a PCB and electrical conductivity test equipment.

According to a yet further aspect of the present invention there is provided a printed circuit board (PCB), the PCB having at least a first surface and a second surface, one or more pre-defined areas defined on the first surface having connection to or comprising a PCB plane for the location of one or more electrical components thereon in use, and one or more test pads provided on the second surface to allow electrical testing of the PCB and/or one or more electrical components located thereon, and wherein two or more connectivity points are provided on the first surface in each of the pre-defined areas, the connectivity points being a spaced distance apart and each point including an inner portion and an outer portion, the inner portion communicating with a test pad and being substantially electrically isolated from the outer portion, the outer portion of two or more connectivity points being electrically connected in the first condition but being substantially electrically isolated from a test pad, the inner and outer portions of the connectivity points capable of electrical connection in a second condition upon application of sufficient solder between the inner and outer portions.

### BRIEF DESCRIPTION OF THE DRAWINGS

Embodiments of the present invention will now be described with reference to the accompanying figures.

FIGS. 1a and 1b illustrate an upper and lower surface of a PCB according to the present invention;

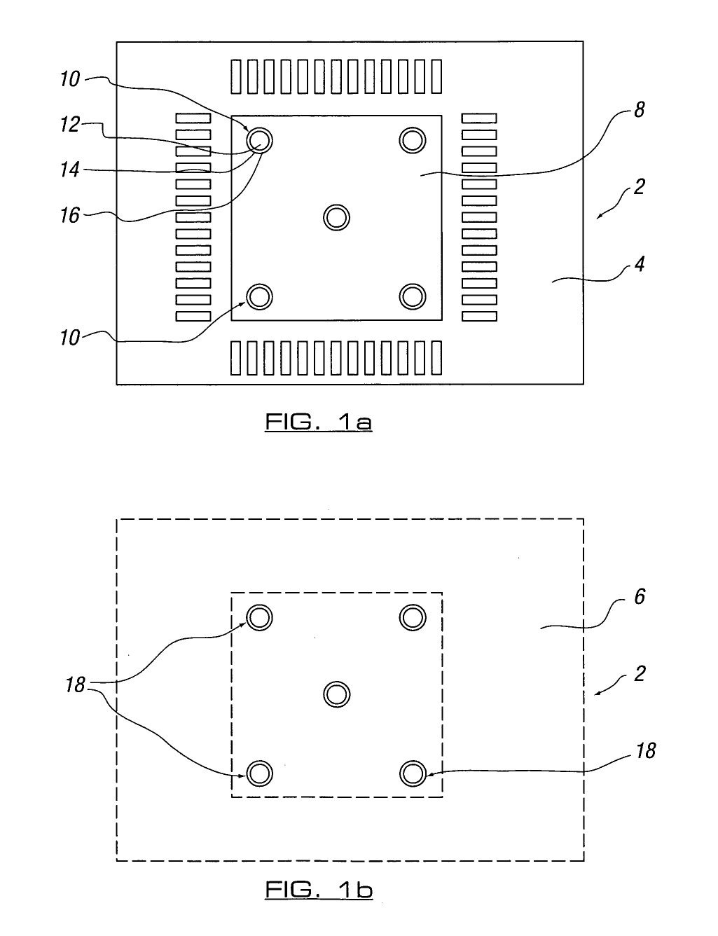

FIG. 2 illustrates means for testing the level of solder provided on the upper surface of the PCB in FIG. 1a using the lower surface of the PCB in FIG. 1b;

FIGS. 3a and 3b illustrate a plan view of an upper surface of a further PCB according to the present invention and a cross sectional view taken through lines A-B in FIG. 3a respectively.

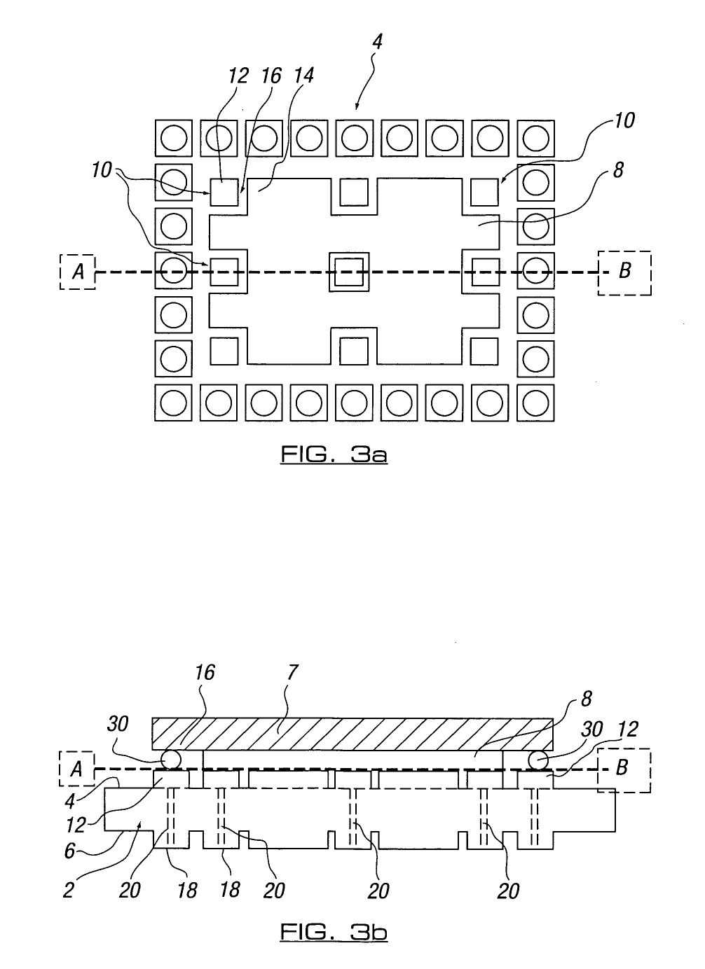

### DETAILED DESCRIPTION OF THE INVENTION

Referring to the Figures, there is illustrated a PCB 2 having an upper surface 4 and a lower surface 6. A PCB plane 8 is provided on upper surface 4 and an electrical component in the form of an integrated circuit (IC) 7 requiring connection to PCB is located on PCB plane 8 in use of the PCB.

A plurality of connectivity points 10 are provided at spaced apart locations on upper surface 4 of PCB plane 8 and, prior to assembly of the electrical component with the PCB plane 8, each connectivity point is in electrical isolation from the other connectivity points.

Each connectivity point 10 includes an inner portion 12, an outer portion 14 and a gap 16 defined between the inner and outer portions. The gap has substantially no solder resist material provided thereon to allow solder to pass between the gap in use of the assembled PCB. Outer portions 14 of all connectivity points 10 are electrically connected together.

A plurality of test pads 18 are provided on lower surface 6 of PCB 2 and vias 20 are provided between the test pads and connectivity points 10 on the opposite surface of the PCB. The vias allow electrical communication or connectivity between test pads 18 and connectivity points 10 on the PCB plane 8 in use. More specifically, the via connects inner portion 12 of connectivity point 10 to test pad 18. As such, in a first condition no solder or insufficient solder is present in the pre-defined area. A test pad communicates with an inner portion of a connectivity point, but the test pad is isolated from the outer portion of the connectivity point due to the gap between the inner and outer portions. As such, despite the outer portions of two or more connectivity points being electrically connected or connectable together, the connectivity cannot be measured due to the test pads not being in communication with the outer portion. When solder fills the gap between the inner and outer portions of connectivity points, electrical connection between the test pad and the outer portion is now made and, thus, the connectivity of two or more connectivity points can be measured via the electrical connections of the outer portions of the points.

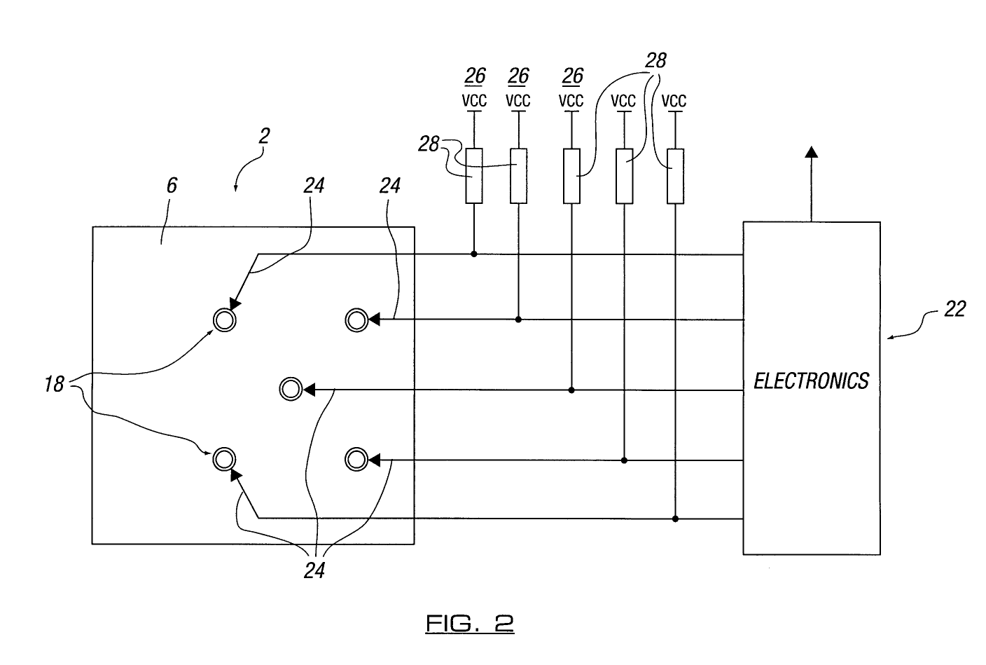

In order to test whether sufficient levels of solder have been provided between IC 7 and PCB plane 8 and, thus, determine whether adequate heat dissipation can take place between the IC and PCB in normal use of the PCB, electrical test circuitry 22 is connected to test pads 18 in a conventional manner as shown in FIG. 2. The conventional electrical test circuitry 22 typically performs a “bed of nails” in-circuit test (ICT) which brings a plurality of electrical contacts, such as pins 24, into contact with test pads 18. Pins 24 are in turn connected to voltage supplies 26, and resistors 28 are located in the circuitry.

If adequate solder has been provided between IC 7 and connectivity points 10, each connectivity point should be capable of electrical connection to another connectivity point 10 on the PCB plane 8. Thus, when an electrical current is applied through the PCB and the solder 30 provided between the IC 7 and PCB plane 8 heats up, the solder bridges gap 16 between the inner and outer portions 14 of connectivity points 10. Since outer portions 14 of all the connectivity points are electrically connected together, bridging of gap 16 allows electrical connectivity to be provided between via 20 connecting inner portion 12 of a connectivity point 10 to a test pad 18 located on the opposite surface of PCB 2. This electrical connectivity is measured using circuitry 22 via connection pins 24. It the gap is bridged by solder and connectivity point 10 is no longer isolated from outer portion 14, the resistance through resistor 28 goes to a closed circuit or very low resistance. If the gap is not bridged by solder, connectivity point 10 will still be isolated from outer portion 14 and, thus, the other connectivity points 10 and the resistance through resistor 28 will remain high.

Thus, it can be seen that apparatus is provided which allows testing of whether there is sufficient solder provided between an electrical component and a PCB plane on a PCB without the use of expensive test apparatus, such as X-ray apparatus.

While the invention has been described with a certain degree of particularly, it is manifest that many changes may be made in the details of construction and the arrangement of components without departing from the spirit and scope of this disclosure. It is understood that the invention is not limited to the embodiments set forth herein for purposes of exemplification, but is to be limited only by the scope of the attached claim or claims, including the full range of equivalency to which each element thereof is entitled.

1. A printed circuit board, said printed circuit board comprising:
at least a first surface and a second surface, one or more pre-defined areas defined on said first surface having connection to or comprising a printed circuit board plane for location of one or more electrical components thereon in use, and wherein two or more connectivity points are provided on said first surface in each of said pre-defined areas, said connectivity points being a spaced distance apart and being substantially electrically isolated from each other in a first condition, the connectivity points capable of electrical connection in a second condition; and
one or more test pads provided on said second surface to allow electrical testing of said printed circuit board and/or one or more electrical components located thereon.

2. A printed circuit board according to claim 1 wherein electrical conducting means are located between said connectivity points to provide said second condition.

3. A printed circuit board according to claim 2 wherein said electrical conducting means includes sufficient solder to form electrical connection between said two or more connectivity points.

4. A printed circuit board according to claim 1 wherein each of said two or more connectivity point includes an inner portion and an outer portion, the inner and outer portions being substantially electrically isolated in said first condition.

5. A printed circuit board according to claim 4 wherein said electrical isolation between said inner and outer portions is provided by a gap or space.

6. A printed circuit board according to claim 5 wherein electrical conducting means are located between said inner and outer portions to fill or cross said gap or space in said second condition.

7. A printed circuit board according to claim 6 wherein said electrical conducting means includes sufficient solder to form electrical connection between said inner and outer portions.

8. A printed circuit board according to claim 5 wherein said gap or space is substantially free of solder resist material or a solder resist component.

9. A printed circuit board according to claim 4 wherein each of said inner and outer portions is substantially continuous in form.

10. A printed circuit board according to claim 1 wherein a number of connectivity points provided in a pre-defined area is sufficient to allow a level of solder connectivity to be determined in said pre-defined area.

11. A printed circuit board according to claim 1 wherein five or more connectivity points are provided in a pre-defined area.

12. A printed circuit board according to claim 3 wherein at least 50% solder coverage of said pre-defined area is required to allow electrical connection between said two or more connectivity points in said second condition.

13. A printed circuit board according to claim 1 wherein said electrical component located on said printed circuit board is an integrated circuit (IC).

14. A printed circuit board according to claim 1 wherein one or more vias are provided between a connectivity point on said first surface and a test pad provided on said second surface.

15. A printed circuit board according to claim 14 wherein a said via is provided between an inner portion of said connectivity point on said first surface and a first test pad on said second surface.

16. A printed circuit board according to claim 14 wherein said one or more vias are arranged substantially perpendicularly to the first and second surfaces of said printed circuit board.

17. A printed circuit board according to claim 1 wherein a “bed of nails” in-circuit test is connected to said test pads of said printed circuit board to determine a level of conductivity between two or more connectivity points.

18. A printed circuit board according to claim 4 wherein said outer portions of each connectivity point in a pre-defined area are electrically connected together in the first and/or second condition.

19. A solder test apparatus including a printed circuit board according to claim 1 and electrical connectivity test equipment.

20. A method for determining an amount of solder provided between two connectivity points in a pre-defined area of a printed circuit board having at least a first surface and a second surface, the pre-defined area defined on said first surface and having connection to or comprising a printed circuit board plane for the location of one or more electrical components thereon in use, and one or more test pads provided on the second surface to allow electrical testing of said printed circuit board and/or one or more electrical components located thereon, and wherein the two or more connectivity points are provided on the first surface in each of said pre-defined areas, said connectivity points being a spaced distance apart and substantially electrically isolated from each other in a first condition, the connectivity points capable of electrical connection in a second condition upon application of sufficient solder and said method including the step of testing the electrical connectivity between said connectivity points using said test pads.

21. A printed circuit board, said printed circuit board having at least a first surface and a second surface, one or more pre-defined areas defined on said first surface having connection to or comprising a PCB plane for the location of one or more electrical components thereon in use, and one or more test pads provided on the second surface to allow electrical testing of said PCB and/or one or more electrical components located thereon, and wherein two or more connectivity points are provided on the first surface in each of said pre-defined areas, said connectivity points being a spaced distance apart and each point including an inner portion and an outer portion, the inner portion communicating with a test pad and being substantially electrically isolated from the outer portion, the outer portion of two or more connectivity points being electrically connected in the first condition but being substantially electrically isolated from a test pad, the inner and outer portions of the connectivity points capable of electrical connection in a second condition upon application of sufficient solder between said inner and outer portions.
